(19) United States
(12) Patent Application Publication
(10) Pub. No.: US 2005/0103186 A1
(43) Pub. Date: May 19, 2005

(54) Music reproducing unit

(76) Inventor: Shouji Ueoka, Kobe (JP)

Correspondence Address: WENDEROTH, LIND & PONACK, L.L.P., 2033 K STREET N. W., SUITE 800, WASHINGTON, DC, 20006-1021, US

(21) Appl. No.: 10/974,672

(22) Filed: Oct. 28, 2004

(30) Foreign Application Priority Data
Oct. 30, 2003 (JP) J.P.A.2003-370617

(51) Int. Cl. H03M 1/00

(52) U.S. Cl. 84/601

(57) ABSTRACT

The present invention teaches a music reproducing unit for selecting songs that a user desires from among a large number of songs stored in a mass storage device such as an HDD without troublesome operation and reproducing the same, which selects songs that the user desires from among multiple songs associated with information concerning songs stored in an HDD and reproduces the same, comprising a setting device for setting a selection criterion X for selecting songs based on intention information of the user obtained through an input device, a selection device for selecting songs that meet the selection criterion X from among the songs stored in the HDD based on the selection criterion X and the information concerning songs, and a reproducing device for reproducing the selected songs when the number of the selected songs is not more than a prescribed number of songs.

### BACKGROUND OF THE INVENTION

1. Field of the Invention

The present invention relates to a music reproducing unit and, more particularly, to a music reproducing unit for selecting songs that a user desires from among a large number of songs stored in a mass storage device such as an HDD (Hard Disk Drive) and reproducing the same.

2. Description of the Relevant Art

Music to be heard in a vehicle is preferably what a driver or an occupant wants to listen to or loves in order to allow the driver to drive comfortably or make a drive enjoyable. Therefore, an audio system for providing music which suits a driver's taste has been proposed. For example, in the Japanese Patent Laid-open 2002-114107, an audio system has been disclosed, which analyzes a driver's taste on the basis of his/her past record of listening, selects songs suiting the driver's taste and provides the driver with the selected songs.

However, since it is extremely difficult to analyze tastes with high accuracy, there is a high possibility that songs which a driver wants to hear are not properly selected in many cases. Moreover, since there is a high possibility that the same songs are selected whenever songs suiting the driver's taste are selected, there is also a high possibility that only songs that the driver is tired of hearing are provided.

Furthermore, music which a person wants to hear varies according to the mood of the moment or the like. A song which one wants to hear today might be what one will not feel like hearing tomorrow in some cases, and conversely, a song which one does not want to hear today might be what one will feel like hearing tomorrow in some cases. Therefore, songs which a user wants to hear are preferably selected depending on the user's mood of the moment or the like.

However, if the user has to do everything for selecting songs, the operation is troublesome. Particularly, with the recent spread of mass storage devices such as an HDD, data concerning a large number of songs (e.g. 1000 songs) can be stored therein. It is not easy to select desired songs from among as many as 1000 songs.

In recent years, for example, data about songs themselves recorded in CDs 2-1 to 2-n (hereinafter, referred to as song data) and TOC (Table Of Contents) information (such as the number of songs and the total performing time) are stored in an HDD 1, as shown in FIG. 8. Moreover, information concerning CDs (such as the title, the number of songs recorded therein, the total performing time of the recorded songs, the singer's name, and the title and performing time of each song) is stored.

As to the song data and the TOC information, data may be read from the CDs 2-1 to 2-n and be stored in the HDD 1. As to the information concerning CDs, since there is a body 3 which provides the information, the information provided by the body 3 may be acquired and be stored in the HDD 1. Here, to which song data stored in the HDD 1 information concerning a CD provided by the body 3 corresponds can be judged from the number of recorded songs and the total performing time. For example, it can be judged that information about a CD having a title of ‘The Great Invention’ (the number of songs: 16 and the total performing time: 51 minutes and 12 seconds) corresponds to the second recorded song data (song data recorded in the CD 2-2).

### SUMMARY OF THE INVENTION

It is an object of the present invention to provide a music reproducing unit for selecting songs that a user desires from among a large number of songs stored in a mass storage device such as an HDD without troublesome operation and reproducing the same.

In order to achieve the above-described object, a music reproducing unit according to a first aspect of the present invention is characterized as a music reproducing unit for selecting songs that a user desires from among multiple songs associated with information concerning songs stored in a storage device and reproducing the same, comprising a selection criterion setting device for setting a selection criterion for selecting songs based on intention information of the user input through an input device, a song selection device for selecting songs that meet the selection criterion set by the selection criterion setting device from among the songs stored in the storage device based on the selection criterion and the information concerning songs, a song quantity judging device for judging whether the quantity of the songs selected by the song selection device is within a prescribed range, and a song reproducing device for reproducing the songs selected by the song selection device according to a predetermined reproducing condition when it is judged that the quantity of the selected songs is within the prescribed range by the song quantity judging device.

By using the music reproducing unit of the first aspect, based on the selection criterion (such as songs sung by Ayumi Hamazaki) that is set on the basis of the intention information of the user (such as “I want to listen to songs of Ayumi Hamazaki.”) and the information concerning songs (such as the title of a CD in which a song is recorded, the singer's name, the title and performing time of the song), songs which meet the selection criterion (such as songs sung by Ayumi Hamazaki) are selected from among the songs stored in the storage device. When it is judged that the quantity of the selected songs (such as the number of songs) is within the prescribed range (e.g. 10 songs or less), the selected songs are reproduced according to the predetermined reproducing condition (such as degrees of freshness of songs) (e.g. the songs are reproduced in the order of the latest date of release). Therefore, with some expression of intention given by the user, songs which the user desires are selected and reproduced, and thus the user can hear the desired songs without troublesome operation.

By using the music reproducing unit of the first aspect, only when the quantity of the selected songs is reduced into the prescribed range, the songs are reproduced. Therefore, it is possible to prevent an occurrence of an event in which the quantity of selected songs is insufficiently reduced, for example, 50 songs or more are selected, so that the reproduction of the songs which the user desires cannot be completed by the end of a drive.

A music reproducing unit according to a second aspect of the present invention is characterized by the predetermined reproducing condition which includes any one of degrees of preference of the user, degrees of freshness of songs and popularities of songs in the music reproducing unit of the first aspect.

By using the music reproducing unit of the second aspect, since the predetermined reproducing condition includes any one of degrees of preference of the user (quantitative degrees obtained from the number of times of listening to a song, the degree of repetition of listening to a song and the like), degrees of freshness of songs (which can be calculated from the date of release) and popularities of songs (which can be obtained from information about a ranking chart to be presented by a body), it is possible to preferentially reproduce songs which the user has frequently heard lately, to preferentially reproduce more fresh songs or to preferentially reproduce currently popular songs. This is useful particularly in cases where all of the selected songs could not be reproduced.

A music reproducing unit according to a third aspect of the present invention is characterized as a music reproducing unit for selecting songs that a user desires from among multiple songs associated with information concerning songs stored in a storage device and reproducing the same, comprising a first selection criterion setting device for setting a first selection criterion for selecting songs based on intention information of the user input through an input device, a first song selection device for selecting songs that meet the first selection criterion set by the first selection criterion setting device from among the songs stored in the storage device based on the first selection criterion and the information concerning songs, a first song quantity judging device for judging whether the quantity of the songs selected by the first song selection device is within a first prescribed range, a first song reproducing device for reproducing the songs selected by the first song selection device according to a first predetermined reproducing condition when it is judged that the quantity of the selected songs is within the first prescribed range by the first song quantity judging device, a request device for making a request of the user to input intention information that is different from said intention information when it is judged that the quantity of the selected songs is not within the first prescribed range by the first song quantity judging device, a second selection criterion setting device for setting another new selection criterion for selecting songs based on intention information of the user input through the input device in response to the request made by the request device, a second song selection device for selecting songs from among the songs stored in the storage device based on the another selection criterion set by the second selection criterion setting device, the first selection criterion and the information concerning songs, a second song quantity judging device for judging whether the quantity of the songs selected by the second song selection device is within a second prescribed range, and a second song reproducing device for reproducing the songs selected by the second song selection device according to a second predetermined reproducing condition when it is judged that the quantity of the selected songs is within the second prescribed range by the second song quantity judging device.

By using the music reproducing unit of the third aspect, when it is judged that the quantity of the selected songs is not within the first prescribed range (e.g. the number of the selected songs is not 10 or less), the user is asked to input another piece of intention information. On the basis of the another selection criterion (such as rhythmical songs) that is set based on the another newly input piece of intention information of the user (e.g. “I want to hear rhythmical songs”), the first selection criterion (such as songs sung by Ayumi Hamazaki) and the information concerning songs, songs which the user desires are selected from among the songs stored in the storage device. For example, songs that meet the another selection criterion and the first selection criterion (such as rhythmical songs sung by Ayumi Hamazaki) are selected from among the songs stored in the storage device.

When it is judged that the quantity of the selected songs (such as the number of songs) is within the second prescribed range (such as 10 songs or less), the selected songs are reproduced according to the second predetermined reproducing condition (such as degrees of freshness of songs) (for example, the songs are reproduced in the order of decreasing freshness). As described above, when the quantity of songs cannot be sufficiently reduced with only the first expression of intention, a chance of a second expression of intention is given to the user, and therefore, the quantity of songs can be further reduced. Thus, it is possible to appropriately reduce the quantity of songs which the user desires.

A music reproducing unit according to a fourth aspect of the present invention is characterized by the request device which has a function of making a request for another input of intention information that is different from said intention information when it is judged that the quantity of the songs is not within the second prescribed range by the second song quantity judging device in the music reproducing unit of the third aspect.

As the case where it is judged that the quantity of the songs is not within the second prescribed range by the second song quantity judging device, a case is exemplified, in which the number of songs to be selected exceeds 10 even if songs that meet both the another selection criterion and the first selection criterion (such as rhythmical songs sung by Ayumi Hamazaki) are selected from among the songs stored in the storage device.

By using the music reproducing unit of the fourth aspect, for example, when it is judged that the quantity of songs which meet both the another selection criterion and the first selection criterion among the songs stored in the storage device is not within the second prescribed range, an input of still another piece of intention information is requested. And songs (such as rhythmical songs having an image of summer that are sung by Ayumi Hamazaki) that meet both another new selection criterion (such as songs having an image of summer) that is set based on another newly input piece of intention information of the user (e.g. “I want to hear summer songs.”) and the already-set selection criteria (such as rhythmical songs sung by Ayumi Hamazaki) are selected.

As described above, when the quantity of songs is not sufficiently reduced, a chance of expressing an intention is repeatedly given to the user, and therefore, the quantity of songs can be further reduced. As a result, it is possible to more appropriately reduce the quantity of songs which the user desires.

A music reproducing unit according to a fifth aspect of the present invention is characterized by the request device which has an information function of informing the user that the quantity of the selected songs is not within the first or second prescribed range when it is judged by the first or second song quantity judging device in the music reproducing unit of the third or fourth aspect.

As the case where it is judged that the quantity of the selected songs is not within the first or second prescribed range by the first or second song quantity judging device, a case is exemplified, in which the number of songs to be selected exceeds 10 and the reduction of the number of songs is not sufficient even if songs that meet the selection criterion set by the first or second selection criterion setting device (such as songs sung by Ayumi Hamazaki) are selected from among the songs stored in the storage device.

By using the music reproducing unit of the fifth aspect, it is possible to accurately inform the user that the reduction of the number of songs is not sufficient, and that still another expression of intention is required.

A music reproducing unit according to a sixth aspect of the present invention is characterized by the request device which has a function of presenting still another selection criterion other than the first selection criterion set by the first selection criterion setting device and the another selection criterion set by the second selection criterion setting device to the user when it is judged that the quantity of the selected songs is not within the first or second prescribed range by the first or second song quantity judging device in any one of the music reproducing units of the third through fifth aspects.

By using the music reproducing unit of the sixth aspect, when the reduction of the number of songs is not sufficient, another selection criterion other than the first selection criterion set by the first selection criterion setting device and the another selection criterion set by the second selection criterion setting device (i.e. the already-set selection criteria) is presented to the user. For example, when the number of songs cannot be sufficiently reduced though an intention “I want to listen to songs of Ayumi Hamazaki.” was expressed by the user, another selection criterion “Would you hear quiet ballad, or rhythmical songs?” is presented to the user. As a result, the user can easily give a next expression of intention.

A music reproducing unit according to a seventh aspect of the present invention is characterized by comprising a response presence judging device for judging the presence or absence of a response to the request made by the request device and a third song reproducing device for reproducing the songs selected by the first or second song selection device according to a third predetermined reproducing condition that is different from the second predetermined reproducing condition when it is judged that there is no response to the request by the response presence judging device in any one of the music reproducing units of the third through sixth aspects.

By using the music reproducing unit of the seventh aspect, when it is judged that there is no response to the request made by the request device (e.g. when there is no response even after 6 seconds elapsed), the songs selected by the first or second song selection device are reproduced according to the third predetermined reproducing condition (such as degrees of freshness of songs) (e.g. the songs are reproduced in the order of decreasing freshness).

That is, even if the number of songs is not sufficiently reduced, the songs are reproduced when there is no response from the user (by considering that no response is an expression of intention of the user). This is useful particularly when the user is satisfied enough with a rough reduction of the number of songs.

A music reproducing unit according to an eighth aspect of the present invention is characterized by the request device which makes a request to the user in a mode appropriate to a prescribed environmental condition in any one of the music reproducing units of the third through seventh aspects.

By using the music reproducing unit of the eighth aspect, a request to the user is made in a mode appropriate to the prescribed environmental condition (such as the user's sex or time zones). For example, when the user is male, the request may be made by female voice, while the request may be made by male voice when the user is female. Or the request may be made by male voice in the morning, while the request may be made by female voice in the afternoon. As a result, it is possible to prevent the user from getting tired of the request.

A music reproducing unit according to a ninth aspect of the present invention is characterized by the second song selection device which selects all songs that meet one, or two or more of the first selection criterion and other new selection criteria set by the second selection criterion setting device from among the songs stored in the storage device, when it is judged that the quantity of the selected songs is below the first or second prescribed range by the first or second song quantity judging device and the other new selection criteria are set by the second selection criterion setting device in any one of the music reproducing units of the third through eighth aspects.

As the case where it is judged that the quantity of the selected songs is below the first or second prescribed range by the first or second song quantity judging device, a case is exemplified, in which the number of songs to be selected is less than a prescribed number of songs (e.g. 3 songs) and a sufficiently large number of songs are not selected even if songs that meet any one of the already-set selection criteria (such as songs sung by Ayumi Hamazaki) are selected from among the songs stored in the storage device.

In that case, the user is asked to input another new piece of intention information by the request device, and another new selection criterion is set by the second selection criterion setting device based on another newly input piece of intention information of the user.

By using the music reproducing unit of the ninth aspect, for example, when the number of songs to be selected is less than 3 and a sufficiently large number of songs are not selected even if songs that meet any one of the already-set selection criteria (such as songs sung by Ayumi Hamazaki) are selected from among the songs stored in the storage device, songs that meet one, or two or more of the first selection criterion and the selection criteria set by the second selection criterion setting device (i.e. including the newly-set selection criterion) (e.g. songs sung by Ayumi Hamazaki or rhythmical songs) are selected. Therefore, it is possible to more appropriately select songs.

A music reproducing unit according to a tenth aspect of the present invention is characterized by the first prescribed range and/or the second prescribed range which is a prescribed range of the number of songs or a prescribed range of the total performing time in any one of the music reproducing units of the first through ninth aspects.

By using the music reproducing unit of the tenth aspect, since the first prescribed range and/or the second prescribed range is the prescribed range of the number of songs (e.g. 10 or less) or the prescribed range of the total performing time (e.g. 50 minutes), it is possible to appropriately reduce the quantity of songs. For example, it is possible to prevent an occurrence of an event where the songs that the user desires cannot be reproduced by the end of a drive since the total performing time of the selected songs is 3 hours or more.

A music reproducing unit according to an eleventh aspect of the present invention is characterized by comprising a prescribed range setting device for setting the first prescribed range and/or the second prescribed range depending on a prescribed range setting condition, wherein the prescribed range setting condition includes any one of a date, a day of the week, a time, a time zone, weather and a destination in any one of the music reproducing units of the first through tenth aspects.

By using the music reproducing unit of the eleventh aspect, the first prescribed range and/or the second prescribed range is set depending on any one of a date, a day of the week, a time, a time zone, weather and a destination. Therefore, for example, the first prescribed range can be set to be about 10 songs in weekdays (when there is a high probability of commuting) and to be about 20-30 songs in holidays (when there is a high probability of taking a trip).

For example, the first prescribed range can be set to be about 10 songs in rush hours (when there is a high probability of a long driving time due to traffic jam) and to be about 5 songs in any time zones but the rush hours, or can be set to be about 20 songs in case of rain (where there is a high probability of a long driving time) and to be about 10 songs in any cases other than rain. Or the first prescribed range can be set according to the distance to the destination or the time required to reach the destination. For example, when the first prescribed range is a prescribed range of the total performing time, the first prescribed range can be set to be a range of the time required to reach the destination.

A music reproducing unit according to a twelfth aspect of the present invention is characterized as a music reproducing unit for selecting songs that a user desires from among multiple songs associated with information concerning songs stored in a storage device and reproducing the same, comprising a selection criterion presenting device for presenting a selection criterion for selecting songs to the user, a support presence judging device for judging whether the selection criterion presented by the selection criterion presenting device was supported by the user based on intention information of the user input through an input device in response to the presentation made by the selection criterion presenting device, a song selection device for selecting songs that meet the selection criterion supported by the user from among the songs stored in the storage device when it is judged that the user supported the selection criterion by the support presence judging device, and a song reproducing device for reproducing the songs selected by the song selection device according to a predetermined reproducing condition.

By using the music reproducing unit of the twelfth aspect, when a selection criterion for selecting songs is presented (e.g. voice guidance “Shall I play your lately favorite songs?” is conducted) and it is judged that the presented selection criterion was supported (was accepted) by the user, songs that meet the selection criterion are selected from among the songs stored in the storage device (e.g. songs which the user has frequently heard lately are selected), and the selected songs are reproduced according to the third predetermined reproducing condition (e.g. degrees of freshness of songs) (e.g. the songs are reproduced in the order of decreasing freshness). Therefore, the user only needs to give a simple expression of intention such as supporting (yes) or not supporting (no), and thus the user can listen to the desired songs without troublesome operation.

A music reproducing unit according to a thirteenth aspect of the present invention is characterized by comprising a start condition satisfaction judging device for judging whether a music reproduction start condition has been satisfied, wherein the selection criterion presenting device presents a selection criterion for selecting songs to the user when it is judged that the music reproduction start condition has been satisfied by the start condition satisfaction judging device in the music reproducing unit of the twelfth aspect.

By using the music reproducing unit of the thirteenth aspect, when it is judged that the music reproduction start condition has been satisfied (e.g. when an ignition switch was turned on, when an audio system or a navigation system was switched on, or when a destination was set), a selection criterion for selecting songs is presented to the user by the selection criterion presenting device. Therefore, it is possible to automatically present the selection criterion with appropriate timing.

A music reproducing unit according to a fourteenth aspect of the present invention is characterized by the music reproduction start condition which is setting of a destination, and the selection criterion presenting device which includes a function of providing the user with information showing a time required to reach the set destination before presenting the selection criterion to the user in the music reproducing unit of the thirteenth aspect.

By using the music reproducing unit of the fourteenth aspect, when a destination is set, information showing a time required to reach the set destination is provided to the user (e.g. voice guidance “It takes about 50 minutes to reach the destination.” is conducted), and a selection criterion for selecting songs is presented. As a result, stage effect is enhanced, so that it is possible to make driving more comfortable or to make a drive more enjoyable. In providing the information, the guidance may be conducted by using the name of a destination instead of ‘the destination’. Moreover, before providing the information, a greeting such as “Today, you are going to ◯◯◯ (the name of a destination), aren't you?” may be added.

A music reproducing unit according to a fifteenth aspect of the present invention is characterized by comprising a request device for making a request of the user to input intention information of the user when it is judged that the user did not support the selection criterion by the support presence judging device, a selection criterion setting device for setting another selection criterion that is different from said selection criterion based on intention information of the user input through an input device in response to the request made by the request device, a song selection device for selecting songs from among the songs stored in the storage device based on the another selection criterion and the information concerning songs, and a song reproducing device for reproducing the songs selected by the song selection device according to a predetermined reproducing condition in any one of the music reproducing units of the twelfth through fourteenth aspects.

By using the music reproducing unit of the fifteenth aspect, when it is judged that the presented selection criterion was not supported by the user, the user is asked to input intention information of the user (e.g. voice guidance “I see. Then, please tell me your favorite artist or album title.” is conducted), and on the basis of the second selection criterion (e.g. only songs sung by Ayumi Hamazaki) that is set based on the input intention information of the user (such as “I want to listen to songs of Ayumi Hamazaki.”) and the information concerning songs, songs that the user desires are selected from among the songs stored in the storage device. For example, songs that meet the second selection criterion (such as songs sung by Ayumi Hamazaki) are selected from among the songs stored in the storage device, and the selected songs are reproduced according to the predetermined reproducing condition (such as degrees of freshness of songs) (e.g. the songs are reproduced in the order of decreasing freshness). Therefore, even if the presented selection criterion is not a criterion that the user likes, it is possible to reproduce songs that the user desires with the newly input intention information of the user.

A music reproducing unit according to a sixteenth aspect of the present invention is characterized by the selection criterion presenting device which presents a selection criterion to the user in a mode appropriate to a prescribed environmental condition in any one of the music reproducing units of the twelfth through fifteenth aspects.

By using the music reproducing unit of the sixteenth aspect, the selection criterion is presented to the user in a mode appropriate to the prescribed environmental condition (such as the user's sex or time zones). For example, when the user is male, the presentation may be made by female voice, while the presentation may be made by male voice when the user is female. Or the presentation may be made by male voice in the morning, while the presentation may be made by female voice in the afternoon. As a result, it is possible to prevent the user from getting tired of the presentation.

### BRIEF DESCRIPTION OF THE DRAWINGS

FIG. 1 is a block diagram schematically showing the principal part of a music reproducing unit according to a first embodiment of the present invention;

FIG. 2 is a diagram showing a part of data that is stored in an HDD;

FIG. 3 is a flowchart showing the processing operation which is performed by a controller in the music reproducing unit according to the first embodiment;

FIG. 4 is a flowchart showing the processing operation which is performed by the controller in the music reproducing unit according to the first embodiment;

FIG. 5 is a flowchart showing the processing operation which is performed by the controller in the music reproducing unit according to the first embodiment;

FIG. 6 is a flowchart showing the processing operation which is performed by the controller in the music reproducing unit according to the first embodiment;

FIG. 7 is a flowchart showing the processing operation which is performed by the controller in the music reproducing unit according to the first embodiment; and

FIG. 8 is a diagram showing a part of data that is stored in an HDD.

### DESCRIPTION OF THE PREFERRED EMBODIMENTS

The preferred embodiments of the music reproducing unit according to the present invention are described below with reference to the drawings annexed hereto.

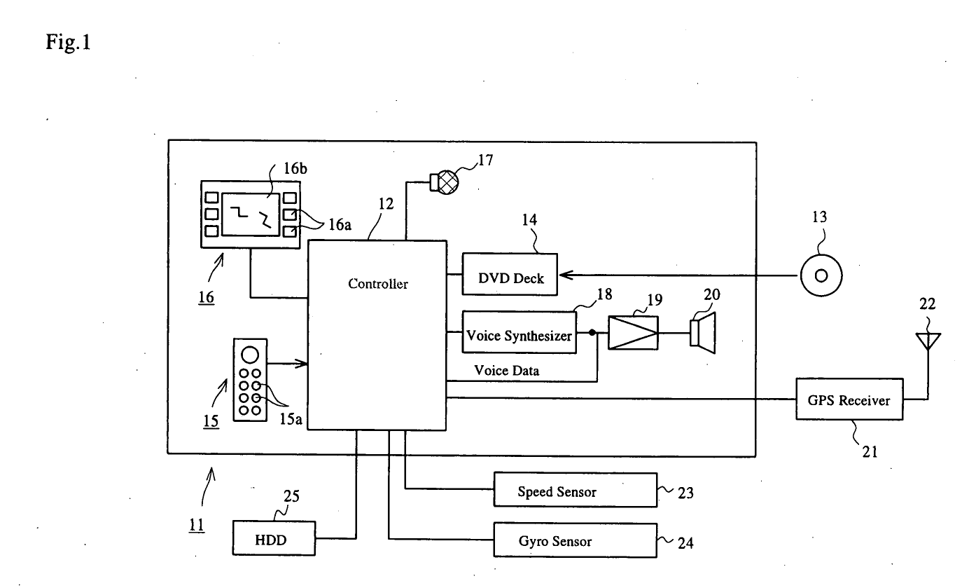

FIG. 1 is a block diagram schematically showing the principal part of a music reproducing unit according to a first embodiment. Numeral reference 11 in the figure represents a music reproducing unit having a navigation function, which is to be mounted on a vehicle M.

The music reproducing unit 11 comprises a controller 12 (comprising a microcomputer), a DVD deck 14 for reading map data and the like from a DVD-ROM 13 in which the map data and the like are stored, a remote control 15 having button switches 15a, a display device 16 having button switches 16a and a display panel 16b, a microphone 17 for converting a voice to electric signals, a voice synthesizer 18 for processing character data from the controller 12 and generating synthesized voice data, an amplifier 19 for amplifying the synthesized voice data generated in the voice synthesizer 18 and a speaker 20 for outputting the amplified synthesized voice data as a voice. Here, as for sound data such as song data, which is not character data, is output through the speaker 20 without passing through the voice synthesizer 18. CDs can also be played on the DVD deck 14.

Multiple infrared LEDs and multiple phototransistors (not shown) are arranged in opposed positions to each other at the top, bottom and both sides of the display panel 16b so that the locations where a finger touches the display panel 16b can be detected. The detected results can be acquired by the controller 12.

A GPS receiver 21 connected to the controller 12 receives GPS signals from satellites through an antenna 22, and the controller 12 can conclude the position of one's vehicle based on the GPS signals. Moreover, to the controller 12, a speed sensor 23 for detecting data concerning the speed of a vehicle M, a gyro sensor 24 for acquiring data concerning the direction in which the vehicle M is heading, and an HDD 25, comprising a magnetic disk (not shown), which can read/write data and stores data of various kinds such as below-described guidance words data, song data and information concerning songs therein, are connected. The HDD 25 reads and outputs required data to the controller 12, or writes data of various kinds on the magnetic disk in response to an instruction from the controller 12. Here, a DVD-ROM in which map data is stored is adopted, but in another embodiment, any storage medium or storage device other than the DVD-ROM may be adopted. For example, an HDD in which map data is stored may be adopted.

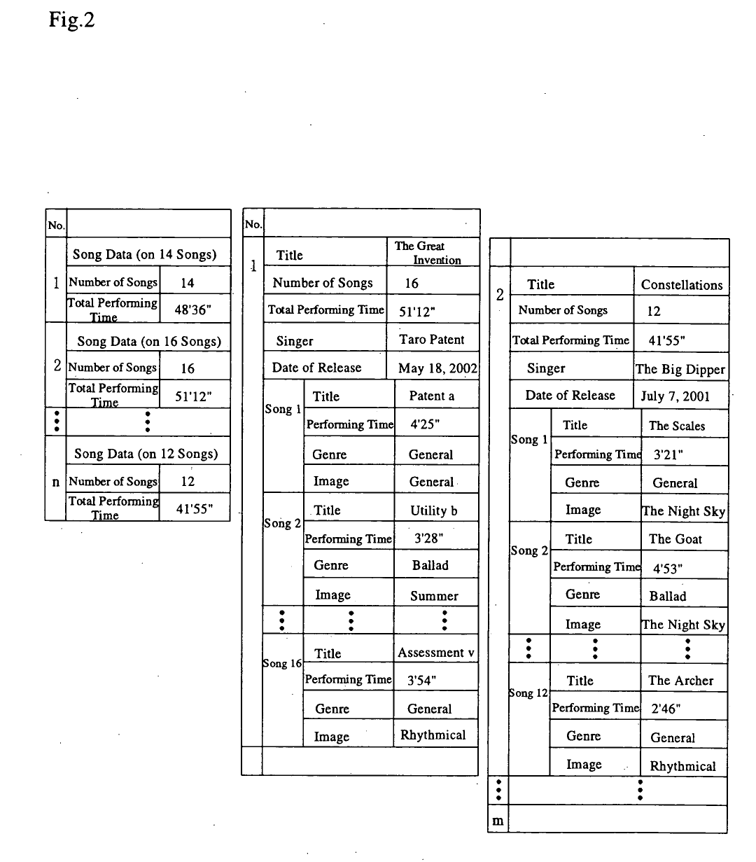

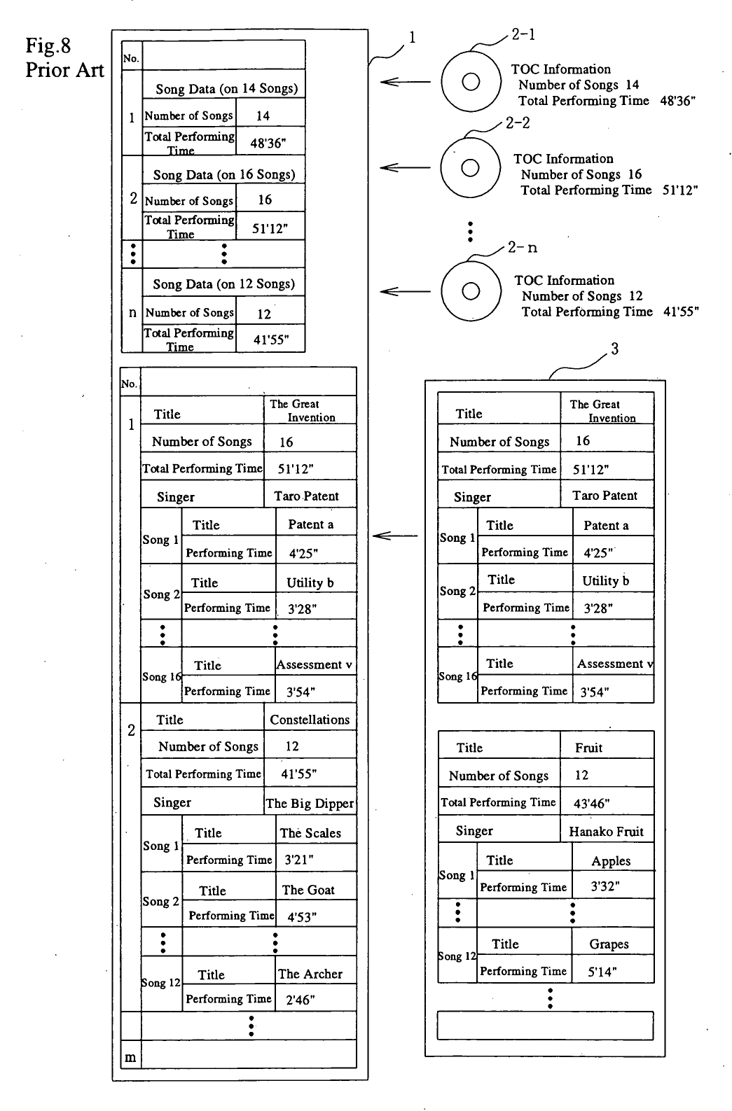

FIG. 2 is a diagram showing a part of data that is stored in the HDD 25. In the HDD 25, data (song data) on songs themselves that are recorded in CDs 2-1 to 2-n (see FIG. 8) and TOC information (such as the number of songs and the total performing time) are stored. Furthermore, information concerning CDs (such as the title, the number of recorded songs, the total performing time of the recorded songs, the singer's name, the date of release, and the title, performing time, genre and image of each song) is stored therein.

As to the song data and the TOC information, data may be read from the CDs 2-1 to 2-n and be stored in the HDD 25. As to the information concerning CDs, since a body which provides the information exists, information to be provided by the body may be acquired and be stored in the HDD 25. Here, to which song data stored in the HDD 25 information concerning a CD provided by the body corresponds can be judged from the number of recorded songs and the total performing time thereof. For example, it can be judged that information concerning a CD having a title of ‘The Great Invention’ (the number of songs: 16 and the total performing time: 51 minutes and 12 seconds), which is stored in the first place, corresponds to song data that is stored in the second place (song data recorded in the CD 2-2).

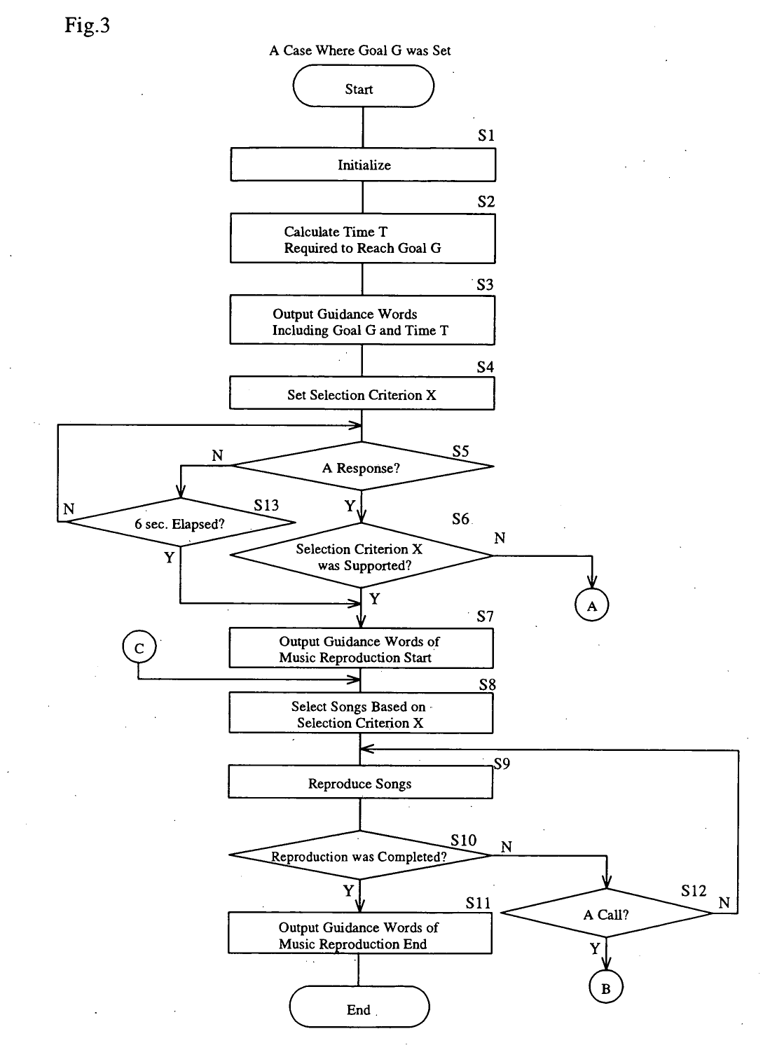

The processing operation [1] which is performed by the controller 12 in the music reproducing unit 11 according to the first embodiment will now be described with reference to the flowcharts shown in FIGS. 3 through 7. Here, the processing operation [1] is conducted when a goal G was set by using a navigation function. First, as an initialization, guidance words data is read from the HDD 25 and is stored in a memory (not shown) of the controller 12 (Step S1).

A time T required to reach the set goal G is calculated (Step S2), and by preparing guidance words data in which the goal G and the time T are included and outputting the prepared guidance words data to the voice synthesizer 18, guidance words are output as a voice through the speaker 20 (Step S3). For example, guidance words “Today, you are going to ◯◯◯ (the name of the goal G), aren't you? It will take about ◯◯ (the Time T) to reach the destination.” are output through the speaker 20. Here, in order to prepare this type of guidance words data, fundamental guidance words data which can be filled in with information about the name of the goal G and the time T may be previously prepared and these pieces of information may fill in the blanks of this guidance words data.

A previously-set selection criterion X (here, songs that a user has frequently heard lately) is presented to the user (Step S4). For example, guidance words “Shall I play your lately favorite songs as BGM before arrival?” are output. Here, as to an output of the guidance words, as described above, guidance words data may be previously prepared, and the guidance words data may be output to the voice synthesizer 18.

Thereafter, based on information obtained through the microphone 17, it is judged whether there was a response from the user (Step S5). When it is judged that there was a response from the user, it is judged whether the contents of the response support the selection criterion X (Step S6). For example, it is judged whether the user produced an affirmative such as “Please.” or “Yes.”

When it is judged that the contents of the response support the selection criterion X (i.e. that a response such as “Please.” was obtained), guidance words of music reproduction start “I see. I start playing music.” are output through the speaker 20. Following those words, guidance words “When you want to listen to a different song, please call me (agent).” are output through the speaker 20 (Step S7). And songs which meet the selection criterion X (i.e. songs that the user has frequently heard lately) are selected from among the songs stored in the HDD 25 (Step S8). Here, although it is not described in detail, as for the reproduced songs, the date and time of reproduction are associated with the songs and are recorded in the HDD 25. Therefore, from this information, the recent status of the user's listening to songs can be judged.

The selected songs are reproduced according to a predetermined reproducing condition (such as degrees of freshness of songs) (e.g. the songs are reproduced in the order of the latest date of release), and the music is output through the speaker 20 (Step S9). Then, it is judged whether the reproduction of all the selected songs was completed (Step S10). When it is judged that the reproduction of all the selected songs was completed, guidance words “I stop playing for a while. Please call me when necessary.” are output through the speaker 20 (Step S11).

Here, although the degrees of freshness of songs are set as the predetermined reproducing condition, the predetermined reproducing condition is not limited to the degrees of freshness of songs. In a music reproducing unit according to another embodiment, degrees of preference of the user are set as the condition, and songs may be reproduced in order of the user's preference or may be reproduced at random.

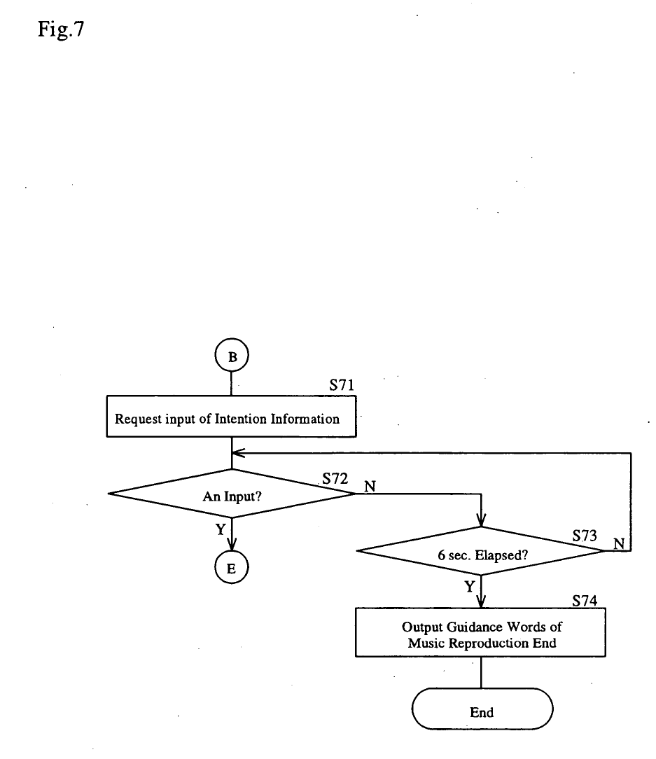

On the other hand, when it is judged in Step S10 that the reproduction of all the selected songs has not been completed yet, it is judged whether the user is calling the agent based on information obtained through the microphone 17 (Step S12). For example, it is judged whether the user said a word “Agent.” or the like. When it is judged that the user is calling the agent, the operation goes to a below-described step S71 (FIG. 7), while it returns directly to Step S9, wherein the reproduction of the songs is continued, when it is judged that the user is not calling the agent.

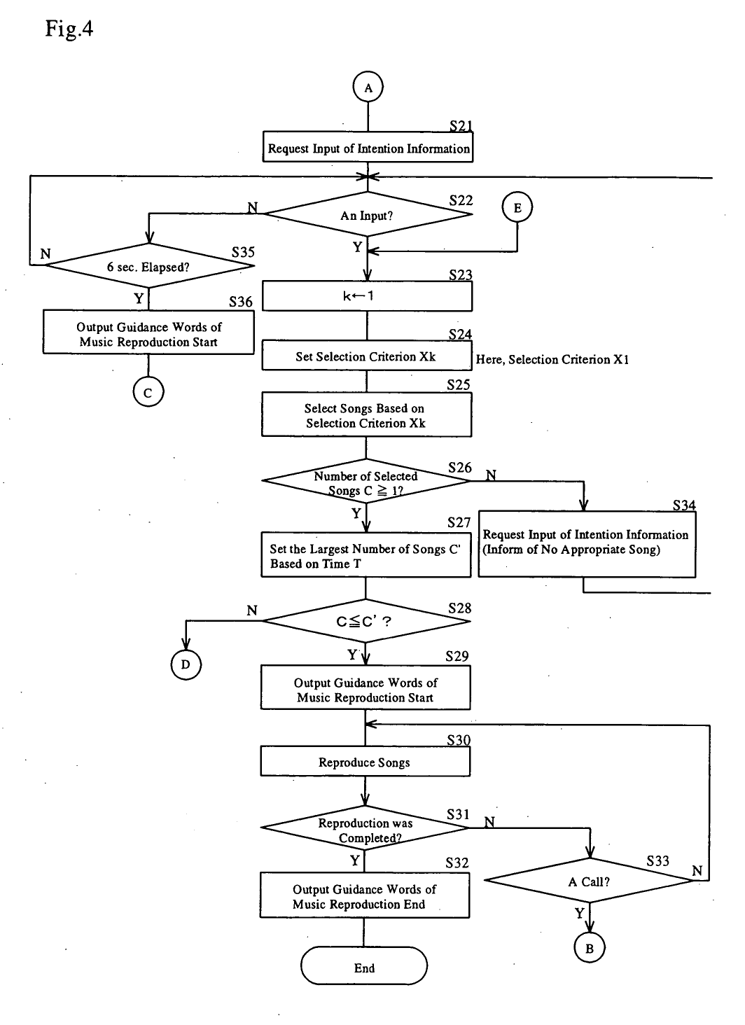

When it is judged in Step S6 that the contents of the response from the user do not support the selection criterion X (i.e. that the user produced a negative such as “No need in particular.” or “No.”), the operation goes to a below-described step S21 (FIG. 4), wherein an input of intention information of the user is requested in order to set a new selection criterion.

When it is judged in Step S5 that there is no response from the user, it is judged whether 6 seconds has elapsed after the selection criterion X was presented to the user (Step S13). When it is judged that 6 seconds has elapsed, it is concluded that the user did not refuse the presented selection criterion X and the operation goes to Step S7.

In Step S21 shown in FIG. 4, for example, by outputting guidance words “I see. Then, please tell me your favorite artist, album title, etc.” through the speaker 20, an input of intention information of the user which is required to set a new selection criterion is requested.

Thereafter, based on information obtained through the microphone 17, it is judged whether there was an input of intention information (e.g. “I want to listen to songs of Ayumi Hamazaki.”) by the user (Step S22). When it is judged that there was an input of intention information by the user, a coefficient k is made 1 (Step S23), and based on the input intention information of the user, a selection criterion Xk (here, a selection criterion X1) for selecting songs is set (Step S24). For example, the selection criterion X1 is set to be ‘songs sung by Ayumi Hamazaki’.

Based on the selection criterion X1 and the information concerning songs, songs that meet the selection criterion X1 (e.g. songs sung by Ayumi Hamazaki) are selected from among the songs stored in the HDD 25 (Step S25). After the selection, it is judged whether the number of selected songs C is 1 or more (i.e. whether an appropriate song or songs are there) (Step S26).

When it is judged that the number of selected songs C is 1 or more, based on the time T required to reach the goal G, the largest number of songs C′ that can be heard before reaching the goal G is found (Step S27). For example, on the supposition that the performing time per song is 5 minutes, in a case in which the time T required to reach the goal G is 100 minutes, the largest number of songs C′ is set to be 20.

It is judged whether the number of selected songs C is not more than the largest number of songs C′ (Step S28). When it is judged that the number of selected songs C is not more than the largest number of songs C′, by preparing guidance words data including the selection criterion X1 and the number of selected songs C and outputting the prepared guidance words data to the voice synthesizer 18, guidance words are output as a voice through the speaker 20 (Step S29). For example, guidance words “There are 15 songs (the number of selected songs C) of Ayumi Hamazaki (the name of a singer). I play the songs in the order of the latest date of release.” are output through the speaker 20.

The songs selected in Step S25 are reproduced according to a predetermined reproducing condition (here, reproduced in the order of the latest date of release), and the music is output through the speaker 20 (Step S30). Thereafter, it is judged whether the reproduction of all the selected songs was completed (Step S31). When it is judged that the reproduction of all the selected songs was completed, guidance words “I stop playing for a while. Please call me when necessary.” are output through the speaker 20 (Step S32).

Here, although the degrees of freshness of songs are set as the predetermined reproducing condition, the predetermined reproducing condition is not limited to the degrees of freshness of songs. In a music reproducing unit according to another embodiment, degrees of preference of the user are set as the condition, and songs may be reproduced in order of the user's preference or may be reproduced at random. However, when a different condition is set as the predetermined reproducing condition instead of the degrees of freshness of songs, the guidance words in Step S29 are modified.

On the other hand, when it is judged in Step S31 that the reproduction of all the selected songs has not been completed yet, it is judged whether the user is calling the agent based on information obtained through the microphone 17 (Step S33). For example, it is judged whether the user said a word “Agent.” When it is judged that the user is calling the agent, the operation goes to the below-described step S71 (FIG. 7), while it returns directly to Step S30, wherein the reproduction of the songs is continued, when it is judged that the user is not calling the agent.

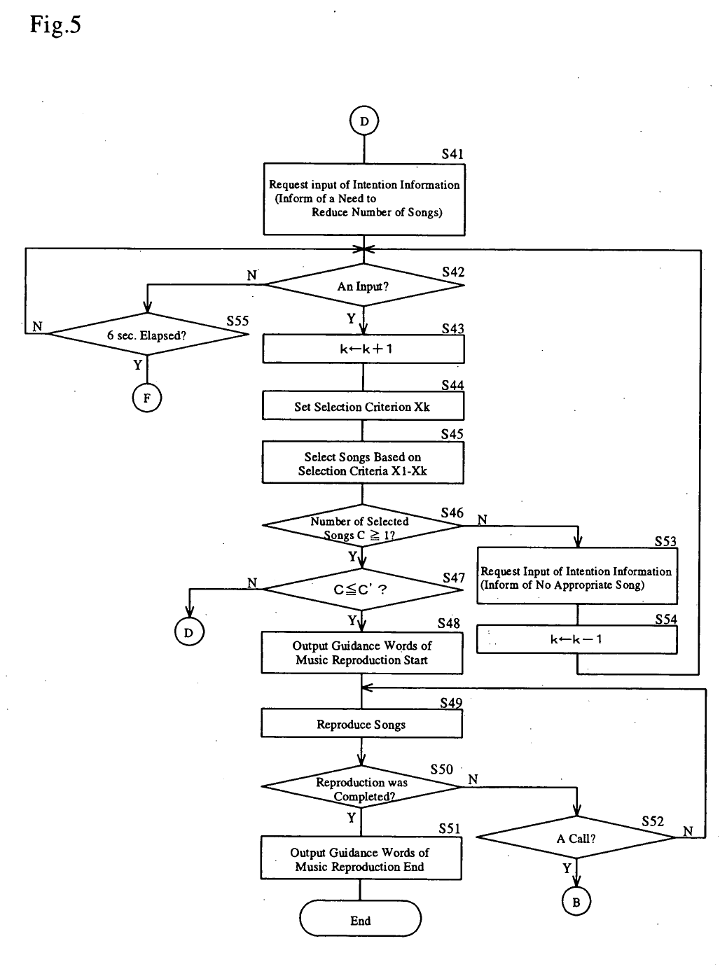

When it is judged in Step S28 that the number of selected songs C is more than the largest number of songs C′ (i.e. that the reduction of the number of songs is not sufficient), the operation goes to a below-described step S41 (FIG. 5), wherein an input of intention information of the user that is required to set still another selection criterion is requested.

When it is judged in Step S26 that the number of selected songs C is less than 1 (i.e. that there is no appropriate song), by outputting guidance words “I cannot find any appropriate songs. Please tell me another artist, album title, etc.” through the speaker 20, an input of intention information of the user that is required to set another selection criterion is requested (Step S34) and the operation returns to Step S22.

When it is judged in Step S22 that there is no input of intention information by the user, it is judged whether 6 seconds has elapsed after the input was requested (Step S35). When it is judged that 6 seconds has elapsed, it is concluded that the user has no special desire concerning a song selection. Guidance words “If you have no special desire, I play songs that you have frequently heard lately.” are output and following those words, guidance words “When you want to listen to a different song, please call me.” are output through the speaker 20 (Step S36). Then, the operation goes to Step S8 (FIG. 3).

In Step S41 shown in FIG. 5, for example, by outputting guidance words in which the number of selected songs C is included, “There are 50 songs of Ayumi Hamazaki and a reduction is necessary. How about rhythmical songs?” through the speaker 20, an input of intention information of the user that is required to set a new selection criterion is requested.

Thereafter, based on information obtained through the microphone 17, it is judged whether there was an input of intention information (e.g. “I want to hear ballad.”) by the user (Step S42). When it is judged that there was an input of intention information by the user, 1 is added to the coefficient k (Step S43) and based on the input intention information of the user, a selection criterion Xk for selecting songs is set (Step S44). For example, a selection criterion X2 is set to be ‘ballad songs’.

Here, an input of intention information of the user is only requested, but in a music reproducing unit according to another embodiment, a selection criterion other than already-set selection criteria (e.g. songs sung by Ayumi Hamazaki) may be presented to the user. For example, another selection criterion is presented like “Would you listen to quiet ballad?” or alternately, “Would you listen to quiet ballad, or rhythmical songs?” Therefore, the user can easily give a next expression of intention.

Based on the selection criteria X1-Xk and the information concerning songs, songs that meet the selection criteria X1-Xk (e.g. ballad songs sung by Ayumi Hamazaki) are selected from among the songs stored in the HDD 25 (Step S45). After the selection, it is judged whether the number of selected songs C is 1 or more (i.e. whether an appropriate song or songs are there) (Step S46).

When it is judged that the number of selected songs C is 1 or more, it is judged whether the number of selected songs C is not more than the largest number of songs C′ (Step S47). When it is judged that the number of selected songs C is not more than the largest number of songs C′, guidance words data in which the selection criteria X1-Xk and the number of selected songs C are used is prepared. By outputting the prepared guidance words data to the voice synthesizer 18, guidance words are output as a voice through the speaker 20 (Step S48). For example, guidance words “There are 6 (the number of selected songs C) ballad songs (the selection criterion X2) sung by Ayumi Hamazaki (the selection criterion X1). I play the songs in the order of the latest date of release.” are output through the speaker 20.

Here, the largest number of songs C′ set in Step S27 is used as it is in Step S47, but considering the fact that the number results from two or more selections of songs, in a music reproducing unit according to another embodiment, the largest number of songs C′ in Step S47 may be C′+a. Moreover, since the vehicle M moves, in a music reproducing unit according to still another embodiment, the largest number of songs C′ may be set again.

The songs selected in Step S45 are reproduced according to a predetermined reproducing condition (here, reproduced in the order of the latest date of release) and the music is output through the speaker 20 (Step S49). Thereafter, it is judged whether the reproduction of all the selected songs was completed (Step S50). When it is judged that the reproduction of all the selected songs was completed, guidance words “I stop playing for a while. Please call me when necessary.” are output through the speaker 20 (Step S51).

Here, the degrees of freshness of songs are set as the predetermined reproducing condition, but the predetermined reproducing condition is not limited to the degrees of freshness of songs. In a music reproducing unit according to another embodiment, degrees of preference of a user are set as the condition, and songs may be reproduced in the order of preference of the user or may be reproduced at random. When the predetermined reproducing condition is set to be a different condition instead of the degrees of freshness of songs, the guidance words in Step S48 are modified.

On the other hand, when it is judged in Step S50 that the reproduction of all the selected songs has not been completed yet, it is judged whether the user is calling the agent based on information obtained through the microphone 17 (Step S52). For example, it is judged whether the user said a word “Agent.” When it is judged that the user is calling the agent, the operation goes to the below-described step S71 (FIG. 7). On the other hand, when it is judged that the user is not calling the agent, it returns directly to Step S49, wherein the reproduction of the songs is continued.

When it is judged in Step S47 that the number of selected songs C is more than the largest number of songs C′ (i.e. the reduction of the number of songs is not sufficient), the operation returns to Step S41, wherein an input of intention information of the user that is required to set still another selection criterion is requested.

When it is judged in Step S46 that the number of selected songs C is less than 1 (i.e. there is no appropriate song), by outputting guidance words in consideration of the selection criterion Xk such as “I cannot find any appropriate songs. How about rhythmical songs?” through the speaker 20, an input of intention information of the user that is required to set another selection criterion is requested (Step S53). 1 is reduced from the coefficient k (Step S54) and then, the operation returns to Step S42.

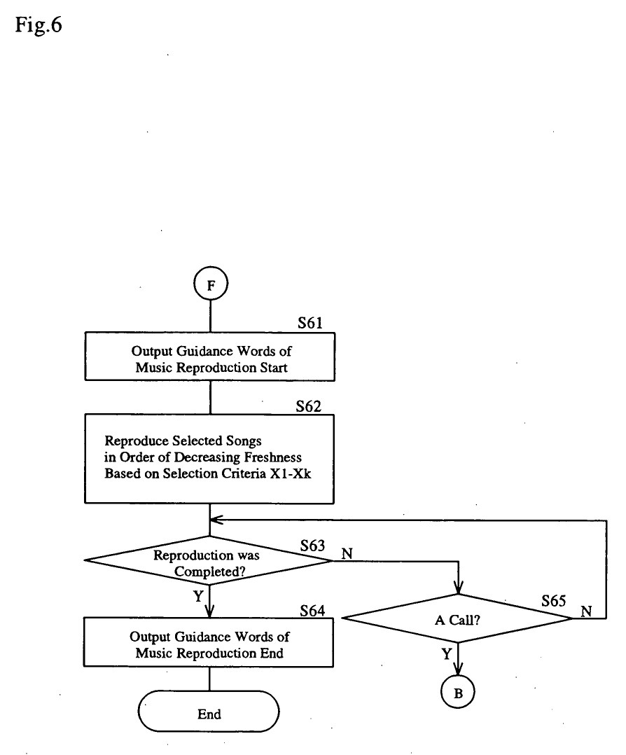

When it is judged in Step S42 that there is no input of intention information by the user, it is judged whether 6 seconds has elapsed after the input was requested (Step S55). When it is judged that 6 seconds has elapsed, it is concluded that the user leaves the reduction of the number of songs to the unit and the operation goes to a below-described step S61 (FIG. 6), wherein the processing for reproducing music is conducted.

In Step 61 shown in FIG. 6, guidance words data in which the selection criteria X1-Xk are used (guidance words data in which the selection criterion X1 is used when the coefficient k is 1) is prepared. And by outputting the prepared guidance words data to the voice synthesizer 18, guidance words are output as a voice through the speaker 20. For example, guidance words “I play songs sung by Ayumi Hamazaki (the selection criterion X1) in the order of the latest date of release.” or “I play ballad songs (the selection criterion X2) sung by Ayumi Hamazaki (the selection criterion X1) in the order of the latest date of release.” are output.

The songs selected based on the selection criteria X1-X2 (i.e. selected in Step S25 or Step S45) are reproduced according to a predetermined reproducing condition (here, reproduced in the order of the latest date of release) and the music is output through the speaker 20 (Step S62). Thereafter, it is judged whether the reproduction of all the selected songs was completed (Step S63). When it is judged that the reproduction of all the selected songs was completed, guidance words “I stop playing for a while. Please call me when necessary.” are output through the speaker 20 (Step S64).

Here, the degrees of freshness of songs are set as the predetermined reproducing condition, but the predetermined reproducing condition is not limited to the degrees of freshness of songs. In a music reproducing unit according to another embodiment, degrees of preference of a user are set as the condition, and songs may be reproduced in the order of preference of the user or may be reproduced at random. When the predetermined reproducing condition is set to be a different condition instead of the degrees of freshness of songs, the guidance words in Step S61 are modified.

On the other hand, when it is judged in Step S63 that the reproduction of all the selected songs has not been completed yet, it is judged whether the user is calling the agent based on information obtained through the microphone 17 (Step S65). For example, it is judged whether the user said a word “Agent.” When it is judged that the user is calling the agent, the operation goes to the below-described step S71 (FIG. 7). On the other hand, when it is judged that the user is not calling the agent, it returns directly to Step S63, wherein the reproduction of the songs is continued.

In Step S71 shown in FIG. 7, for example, by outputting guidance words “Yes, did you call me? Please let me know your favorite artist, album title, etc.” through the speaker 20, an input of intention information of the user that is required to set a new selection criterion is requested.

Thereafter, based on information obtained through the microphone 17, it is judged whether there was an input of intention information (e.g. “I want to listen to songs of Ayumi Hamazaki.”) by the user (Step S72). When it is judged that there was an input of intention information by the user, the operation goes to Step S23 (FIG. 4), wherein the processing operation for reproducing songs is conducted.

On the other hand, when it is judged that there was no input of intention information by the user, it is judged whether 6 seconds has elapsed after the input was requested (Step S73). When it is judged that 6 seconds has elapsed, it is concluded that the user does not desire the reproduction of songs and guidance words “Please call me again when necessary.” are output through the speaker 20 (Step S74).

By using the music reproducing unit according to the first embodiment, on the basis of the selection criterion X1 (e.g. songs sung by Ayumi Hamazaki) that is set based on the intention information of the user (e.g. “I want to listen to songs of Ayumi Hamazaki.”) and the information concerning songs (e.g. the title of a CD in which a song is recorded, the singer's name, the title and performing time of the song), songs that meet the selection criterion X1 (e.g. songs sung by Ayumi Hamazaki) are selected from among the songs stored in the HDD 25. When it is judged that the number of selected songs C exceeds the largest number of songs C′ (e.g. 10 songs), the selected songs are reproduced according to a predetermined reproducing condition (e.g. degrees of freshness of songs) (e.g. the songs are reproduced in the order of the latest date of release). Therefore, since desired songs are selected and reproduced with some expression of intention given by the user, the user can listen to songs which the user desires without troublesome operation.

Songs are reproduced only when the number of selected songs C is reduced to the largest number of songs C′. Therefore, it is possible to prevent an occurrence of an event where the reproduction of songs which the user desires cannot be completed by the end of a drive since the reduction of the number of songs is not sufficient, for example, 50 songs or more are selected.

By using the music reproducing unit according to the first embodiment, a selection criterion for selecting songs is presented (e.g. voice guidance “Shall I play your lately favorite songs?” is conducted). When it is judged that the presented selection criterion was supported (was accepted) by the user, songs that meet the selection criterion X are selected from among the songs stored in the HDD 25 (e.g. songs which the user has frequently heard lately are selected) and the selected songs are reproduced according to a predetermined reproducing condition (e.g. degrees of freshness of songs) (e.g. the songs are reproduced in the order of decreasing freshness). Therefore, since all the user needs to do is to give a simple expression of intention such as supporting (yes) or not supporting (no), the user can hear songs which the user desires without troublesome operation.

Here, in the music reproducing unit according to the first embodiment, communications of various kinds are conducted by voice, but in a music reproducing unit according to another embodiment, the above-described communications may be conducted through button input or screen display, or both in combination. In a music reproducing unit according to still another embodiment, the mode of guidance or the like by the unit (e.g. a voice of an agent) may be changed depending on a prescribed environmental condition (e.g. a user's sex or time zones).

For example, when the user is male, the guidance may be conducted by female voice, while the guidance may be conducted by male voice when the user is female. Or the guidance may be conducted by male voice in the morning, while the guidance may be conducted by female voice in the afternoon. As a result, it is possible to prevent the user from getting tired of the guidance. Here, in order to realize the alteration of the mode of the guidance and the like depending on the user's sex, the user may be allowed to previously register the user's sex.

1. A music reproducing unit for selecting songs that a user desires from among multiple songs associated with information concerning songs stored in a storage device and reproducing the same, comprising:
a selection criterion setting device for setting a selection criterion for selecting songs based on intention information of the user input through an input device;
a song selection device for selecting songs that meet the selection criterion set by the selection criterion setting device from among the songs stored in the storage device based on the selection criterion and the information concerning songs;
a song quantity judging device for judging whether the quantity of the songs selected by the song selection device is within a prescribed range; and
a song reproducing device for reproducing the songs selected by the song selection device according to a predetermined reproducing condition when it is judged that the quantity of the selected songs is within the prescribed range by the song quantity judging device.

2. A music reproducing unit according to claim 1, wherein the predetermined reproducing condition includes any one of degrees of preference of the user, degrees of freshness of songs and popularities of songs.

3. A music reproducing unit for selecting songs that a user desires from among multiple songs associated with information concerning songs stored in a storage device and reproducing the same, comprising:
a first selection criterion setting device for setting a first selection criterion for selecting songs based on intention information of the user input through an input device;
a first song selection device for selecting songs that meet the first selection criterion set by the first selection criterion setting device from among the songs stored in the storage device based on the first selection criterion and the information concerning songs;
a first song quantity judging device for judging whether the quantity of the songs selected by the first song selection device is within a first prescribed range;
a first song reproducing device for reproducing the songs selected by the first song selection device according to a first predetermined reproducing condition when it is judged that the quantity of the selected songs is within the first prescribed range by the first song quantity judging device;
a request device for making a request of the user to input intention information that is different from said intention information when it is judged that the quantity of the selected songs is not within the first prescribed range by the first song quantity judging device;
a second selection criterion setting device for setting another new selection criterion for selecting songs based on intention information of the user input through the input device in response to the request made by the request device;
a second song selection device for selecting songs from among the songs stored in the storage device based on the another selection criterion set by the second selection criterion setting device, the first selection criterion and the information concerning songs;
a second song quantity judging device for judging whether the quantity of the songs selected by the second song selection device is within a second prescribed range; and
a second song reproducing device for reproducing the songs selected by the second song selection device according to a second predetermined reproducing condition when it is judged that the quantity of the selected songs is within the second prescribed range by the second song quantity judging device.

4. A music reproducing unit according to claim 3, wherein the request device has a function of making a request for another input of intention information that is different from said intention information when it is judged that the quantity of the songs is not within the second prescribed range by the second song quantity judging device.

5. A music reproducing unit according to claim 3, wherein the request device has an information function of informing the user that the quantity of the selected songs is not within the first or second prescribed range when it is judged by the first or second song quantity judging device.

6. A music reproducing unit according to claim 3, wherein the request device has a function of presenting still another selection criterion other than the first selection criterion set by the first selection criterion setting device and the another selection criterion set by the second selection criterion setting device to the user when it is judged that the quantity of the selected songs is not within the first or second prescribed range by the first or second song quantity judging device.

7. A music reproducing unit according to claim 3, comprising:
a response presence judging device for judging the presence or absence of a response to the request made by the request device; and
a third song reproducing device for reproducing the songs selected by the first or second song selection device according to a third predetermined reproducing condition that is different from the second predetermined reproducing condition when it is judged that there is no response to the request by the response presence judging device.

8. A music reproducing unit according to claim 3, wherein the request device makes a request to the user in a mode appropriate to a prescribed environmental condition.

9. A music reproducing unit according to claim 3, wherein the second song selection device selects all songs that meet one, or two or more of the first selection criterion and other new selection criteria set by the second selection criterion setting device from among the songs stored in the storage device, when it is judged that the quantity of the selected songs is below the first or second prescribed range by the first or second song quantity judging device and the other new selection criteria are set by the second selection criterion setting device.

10. A music reproducing unit according to claim 1, wherein the prescribed range is a prescribed range of the number of songs or a prescribed range of the total performing time.

11. A music reproducing unit according to claim 3, wherein the prescribed range is a prescribed range of the number of songs or a prescribed range of the total performing time.

12. A music reproducing unit according to claim 1, comprising:
a prescribed range setting device for setting the first prescribed range depending on a prescribed range setting condition, wherein:
the prescribed range setting condition includes any one of a date, a day of the week, a time, a time zone, weather and a destination.

13. A music reproducing unit according to claim 3, comprising:
a prescribed range setting device for setting the first prescribed range and/or the second prescribed range depending on a prescribed range setting condition, wherein:
the prescribed range setting condition includes any one of a date, a day of the week, a time, a time zone, weather and a destination.

14. A music reproducing unit for selecting songs that a user desires from among multiple songs associated with information concerning songs stored in a storage device and reproducing the same, comprising:
a selection criterion presenting device for presenting a selection criterion for selecting songs to the user;
a support presence judging device for judging whether the selection criterion presented by the selection criterion presenting device was supported by the user based on intention information of the user input through an input device in response to the presentation made by the selection criterion presenting device;
a song selection device for selecting songs that meet the selection criterion supported by the user from among the songs stored in the storage device when it is judged that the user supported the selection criterion by the support presence judging device; and
a song reproducing device for reproducing the songs selected by the song selection device according to a predetermined reproducing condition.

15. A music reproducing unit according to claim 14, comprising a start condition satisfaction judging device for judging whether a music reproduction start condition has been satisfied, wherein:
the selection criterion presenting device presents a selection criterion for selecting songs to the user when it is judged that the music reproduction start condition has been satisfied by the start condition satisfaction judging device.

16. A music reproducing unit according to claim 15, wherein:
the music reproduction start condition is setting of a destination; and
the selection criterion presenting device includes a function of providing the user with information showing a time required to reach the set destination before presenting the selection criterion to the user.

17. A music reproducing unit according to claim 14, comprising:
a request device for making a request of the user to input intention information of the user when it is judged that the user did not support the selection criterion by the support presence judging device;
a selection criterion setting device for setting another selection criterion that is different from said selection criterion based on intention information of the user input through an input device in response to the request made by the request device;
a song selection device for selecting songs from among the songs stored in the storage device based on the another selection criterion and the information concerning songs; and
a song reproducing device for reproducing the songs selected by the song selection device according to a predetermined reproducing condition.

18. A music reproducing unit according to claim 14, wherein the selection criterion presenting device presents a selection criterion to the user in a mode appropriate to a prescribed environmental condition.

19. A music reproducing unit for selecting songs that a user desires from among multiple songs associated with information concerning songs stored in a storage device and reproducing the same, comprising:
a selection criterion setting device for setting a selection criterion for selecting songs based on intention information of the user input through an input device;
a song selection device for selecting songs that meet the selection criterion set by the selection criterion setting device from among the songs stored in the storage device based on the selection criterion and the information concerning songs;
a song quantity judging device for judging whether the quantity of the songs selected by the song selection device is within a prescribed range; and
a song reproducing device for reproducing the selected songs in order when it is judged that the quantity of the selected songs is within the prescribed range by the song quantity judging device.

20. A music reproducing unit according to claim 19, wherein the song reproducing device reproduces the selected songs in order according to a predetermined reproducing condition when it is judged that the quantity of the selected songs is within the prescribed range by the song quantity judging device.

21. A music reproducing unit according to claim 20, wherein the predetermined reproducing condition includes any one of degrees of preference of a user, degrees of freshness of songs and popularities of songs.

22. A music reproducing unit according to claim 20, wherein the music reproducing device reproduces songs in order by considering that the predetermined reproducing condition is the order of the lately most frequently heard song when intention information of the user is not input through the input device for a prescribed period of time.
